(19) United States
(12) Patent Application Publication
(10) Pub. No.: US 2024/0184267 A1
(43) Pub. Date: Jun. 6, 2024

(54) GENERATING METHOD, PATTERN FORMING METHOD, ARTICLE MANUFACTURING METHOD, STORAGE MEDIUM, AND INFORMATION PROCESSING APPARATUS

(71) Applicant: CANON KABUSHIKI KAISHA, Tokyo (JP)

(72) Inventor: TSUTOMU TERAO, Tochigi (JP)

(21) Appl. No.: 18/488,529

(22) Filed: Oct. 17, 2023

(30) Foreign Application Priority Data
Oct. 25, 2022 (JP) 2022-170868

(51) Int. Cl. G05B 19/4099

(52) U.S. Cl. CPC G05B 19/4099; G05B 2219/45031

(57) ABSTRACT

The present invention provides a generating method of generating a driving profile for driving an object, the method comprising: obtaining a target driving amount by which the object is to be driven by the driving profile; creating, based on the target driving amount, a provisional profile including an acceleration period in which the object is accelerated so as to change an acceleration nonlinearly and a deceleration period in which the object is decelerated so as to change a deceleration nonlinearly; and determining the driving profile based on the provisional profile.

### BACKGROUND OF THE INVENTION

### Field of the Invention

The present invention relates to a generating method of generating a driving profile for driving an object, a pattern forming method using the generating method, an article manufacturing method, a storage medium, and an information processing apparatus.

### Description of the Related Art

As a lithography apparatus used in a manufacturing process for semiconductor devices and the like, an exposure apparatus is known, which transfers the pattern of an original plate onto a substrate via a projection optical system. The lithography apparatus is required to improve the throughput (productivity). In order to improve the throughput of the lithography apparatus, it is effective to shorten the driving time of a positioning apparatus, a so-called stage, which holds and positions a wafer or reticle.

Japanese Patent Laid-Open No. 2001-140972 discloses a target value waveform generating unit that generates a target value waveform for issuing an instruction to drive the stage. Such a target value waveform generating unit can be referred to as a profiler. The target value waveform generated by the profiler can be referred to as a profile (a driving profile for the stage).

In addition, as an example of the profile, FIG. 4 in Japanese Patent Laid-Open No. 2015-216326 shows an acceleration profile that changes the acceleration nonlinearly (to be sometimes referred to as an S-shaped acceleration profile hereinafter). FIG. 7 in Japanese Patent Laid-Open No. 2015-216326 shows an acceleration profile that changes the acceleration linearly (to be sometimes referred to as a trapezoidal acceleration profile).

With regard to a drive command for the positioning apparatus, an S-shaped acceleration profile is better than a trapezoidal acceleration profile in the settling time after driving. However, with an S-shaped acceleration profile, as the constant speed period provided between an acceleration period and a deceleration period decreases, an abrupt force change can occur between the acceleration period and the deceleration period. This change can cause an object such as the main body of a stage or lithography apparatus to vibrate and can give an influence on the settling time.

### SUMMARY OF THE INVENTION

The present invention provides a technique that can generate a driving profile so as to, for example, reduce the force change between an acceleration period and a deceleration period.

According to one aspect of the present invention, there is provided a generating method of generating a driving profile for driving an object, the method comprising: obtaining a target driving amount by which the object is to be driven by the driving profile; creating, based on the target driving amount, a provisional profile including an acceleration period in which the object is accelerated so as to change an acceleration nonlinearly and a deceleration period in which the object is decelerated so as to change a deceleration nonlinearly; and determining the driving profile based on the provisional profile, wherein in the creating, the provisional profile is created by adjusting a length of a constant speed period in which the object is moved at a constant speed between the acceleration period and the deceleration period so as to achieve the target driving amount, and wherein in the determining, in a case where the length of the constant speed period of the provisional profile is not more than a threshold, the driving profile is determined by processing the provisional profile so as to make an absolute value of a Jerk include no zero portion between the acceleration period and the deceleration period.

Further features of the present invention will become apparent from the following description of exemplary embodiments with reference to the attached drawings.

### BRIEF DESCRIPTION OF THE DRAWINGS

FIGS. 1A to 1E are graphs for explaining problems in an S-shaped acceleration profile;

FIGS. 2A to 2E are graphs for explaining the comparison between an S-shaped acceleration profile and a trapezoidal acceleration profile;

FIGS. 3A to 3E are graphs showing an example of an S-shaped acceleration profile (a provisional profile before processing);

FIGS. 4A to 4E are graphs showing an example of a provisional profile after processing according to Example 1;

FIGS. 5A to 5E are graphs showing an example of a provisional profile after processing according to Example 2;

FIGS. 6A to 6E are graphs showing an example of a provisional profile after processing according to Example 3;

FIG. 7 is a flowchart showing a generating method of generating a driving profile; and

FIG. 8 is a schematic view showing an example of the arrangement of an exposure apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

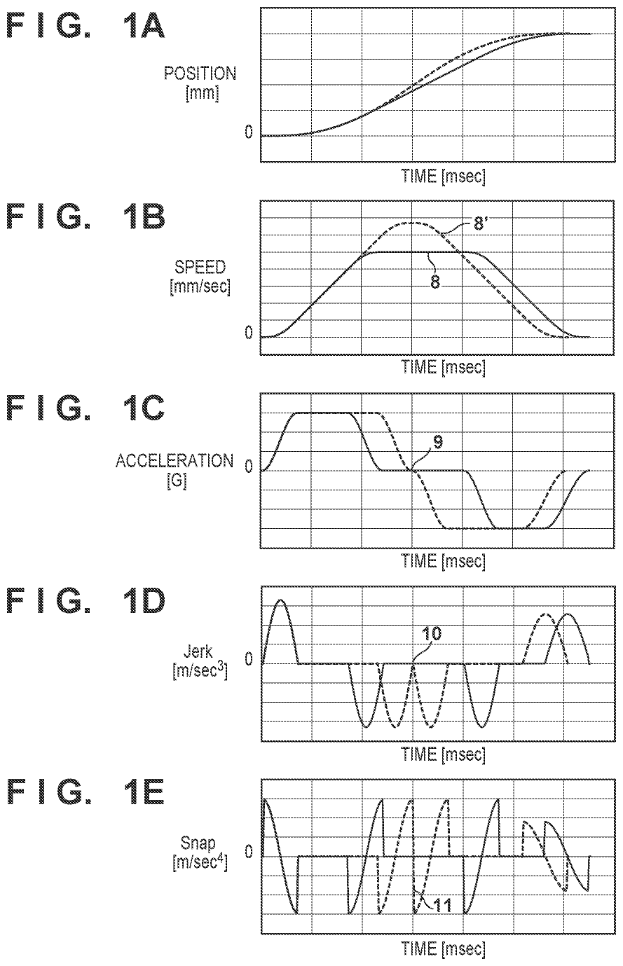

Referring to FIGS. 1A to 1E, two types of S-shaped acceleration profiles are respectively indicated by the solid and broken lines. The S-shaped acceleration profile is a driving profile for driving an object so as to change the absolute value of the acceleration nonlinearly (in an S-shaped manner) and defines target values (a position, speed, acceleration, Jerk, Snap, and the like) for driving the object. FIG. 1A shows the position of the object with respect to the elapsed time (time). FIG. 1B shows the speed with respect to the elapsed time. FIG. 1C shows the acceleration with respect to the elapsed time. FIG. 1D shows the change in acceleration (to be sometimes referred to as the “Jerk” hereinafter) with respect to the elapsed time. FIG. 1E shows the change in Jerk (to be sometimes referred to as the “Snap” hereinafter) with respect to the elapsed time. The respective graphs shown in FIGS. 1A to 1E show drive commands for the same driving profile and exhibit differential relations. Note that the driving profile shown in FIGS. 1A to 1E exhibits an S-shaped (nonlinear) increase or decrease in the absolute value of the acceleration shown in FIG. 1C and hence can be called an S-shaped acceleration profile. The profiles respectively indicated by the solid and broken lines in FIGS. 1A to 1E differ only in maximum speed.

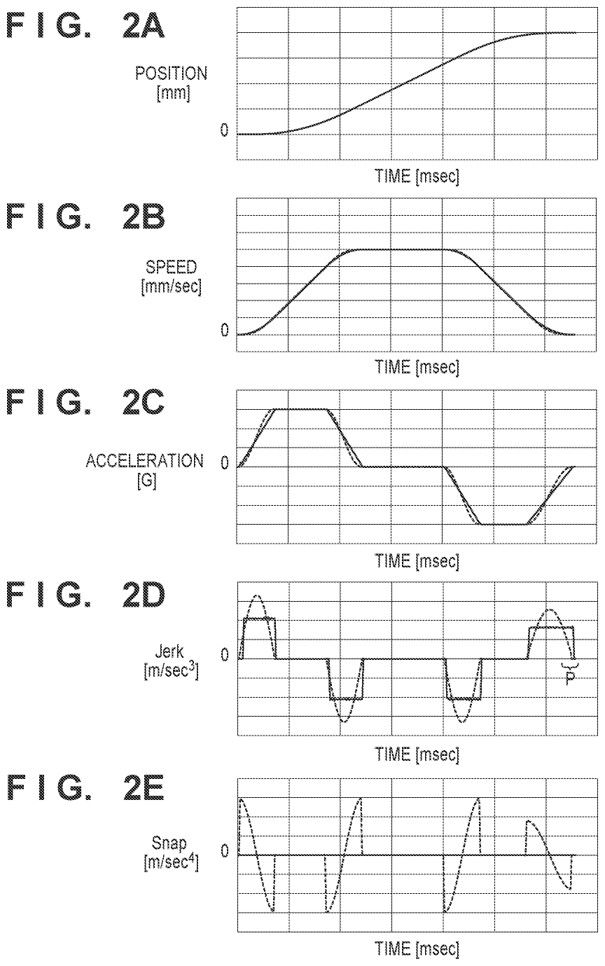

In this case, the S-shaped acceleration profile and the trapezoidal acceleration profile will be compared with each other. The trapezoidal acceleration profile is a driving profile that drives an object so as to linearly increase or decrease the absolute value of the acceleration, as shown in FIGS. 2A to 2E. The Jerk immediately before the end of driving (a period P) of an object based on a trapezoidal acceleration profile is the value obtained by dividing the acceleration by the Jerk time (that is, the value obtained by differentiating the acceleration) and hence increases. In contrast to this, with the S-shaped acceleration profile, as shown in FIG. 1D, the Jerk immediately before the end of driving approaches more zero as compared with the trapezoidal acceleration profile. Accordingly, the S-shaped acceleration profile is smaller than the trapezoidal acceleration profile in force change occurring immediately before the end of driving and hence has an effect of suppressing the settling time after the driving. Therefore, when an object is to be driven, the S-shaped acceleration profile is preferably used more than the trapezoidal acceleration profile. Referring to FIGS. 2A to 2E, as drive commands for a trapezoidal acceleration profile, the position, speed, acceleration, Jerk, and Snap of the object are respectively indicated by the solid lines. Referring to FIGS. 2A to 2E, for comparison, the S-shaped acceleration profile is indicated by the broken line.

An S-shaped acceleration profile having undergone a change in maximum speed will be described next. As indicated by the broken lines in FIGS. 1A to 1E, increasing the maximum speed can shorten the driving time (moving time) to the target position. On the other hand, increasing the maximum speed will shorten the constant speed interval in which the object is driven at an even speed (a constant speed). In the case shown in FIG. 1B, a speed profile 8 including a constant speed interval as indicated by the solid line is changed to a speed profile 8′ including no constant speed interval as indicated by the broken line.

If the S-shaped acceleration profile includes no constant speed interval, acceleration and deceleration are instantly switched at the timing denoted by reference numeral 9 in FIG. 1C. At this timing, as denoted by reference numeral 10 in FIG. 1D, the speed can steeply change at the transition point between acceleration and deceleration via a point at which the Jerk becomes zero. In addition, the Snap at this timing can steeply change at the transition point between acceleration and deceleration as denoted by reference numeral 11 in FIG. 1E. At this timing, the profile increases to the highest speed and hence undergoes a steep force change. Accordingly, the large kinetic energy may cause disturbance.

A steep force change of a drive command based on such a profile excites an object (for example, the stage structure body) having an eigenvalue to vibrate a drive axis. In addition, this influences the non-drive axes linked to the drive axis. For example, if an object is the stage of the exposure apparatus, when the X-axis of the stage is driven, the driving can cause the vibration of the Y-axis, the Z-axis, and their tilt axes which are scarcely driven. This can also influence a damping control mechanism for reducing the vibration of the apparatus main body due to the stage reaction force and cause the apparatus body and the lens to vibrate because of uncontrollable reaction force at the time of stage driving. This can increase the settling time of the stage and the apparatus main body at the time of stage driving of the exposure apparatus and affect the throughput of the exposure apparatus.

With reference to the broken lines in FIGS. 1A to 1E described above, the case in which the S-shaped acceleration profile includes no constant speed interval has been described. Similar to this case, in a case in which the length of the constant speed interval in the S-shaped acceleration profile is equal to or less than a threshold, a steep change in Jerk can occur between acceleration and deceleration. The threshold can be set to the length of a constant speed interval when the vibration caused in the object reaches a specified value by using an experiment, simulation, or the like. The threshold can be set to, for example, zero or a value near zero.

### First Embodiment

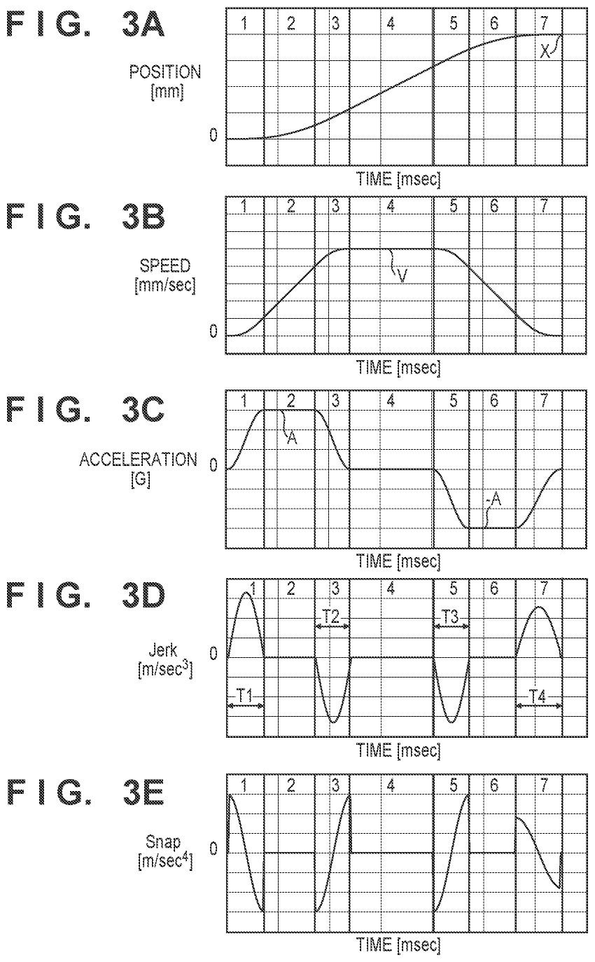

The first embodiment of the present invention will be described. FIGS. 3A to 3E are graphs for explaining drive commands for the S-shaped acceleration profile separately for the respective intervals in detail. FIGS. 3A to 3E respectively indicate the position, speed, acceleration, Jerk, and Snap of the object as drive commands for the S-shaped acceleration profile. The numbers 1 to 7 attached to the upper portion of each of FIGS. 3A to 3E represent the intervals (first to seventh intervals) of the profile.

The first interval is an interval (the first increase interval, acceleration increase interval, or acceleration rise interval) in which the acceleration is increased nonlinearly (in an S-shaped manner) so as to change the absolute value of Jerk in a curve (for example, parabolically) and is sometimes written as “Jerk 1” hereinafter. The second interval is an interval (constant speed interval) in which the acceleration is constant. The third interval is an interval (the first decrease interval, acceleration decrease interval, or acceleration fall interval) in which the acceleration is reduced nonlinearly (in an S-shaped manner) so as to change the absolute value of Jerk in a curve (for example, parabolically) and is sometimes written as “Jerk 2” hereinafter. The first to third intervals constitute an acceleration period in which the object is accelerated so as to change the acceleration nonlinearly.

The fourth interval is a constant speed interval (that is, a constant speed period in which the object is moved at a constant speed) in which the acceleration is zero and the speech is constant. The fifth interval is an interval (the second increase interval, deceleration increase interval, or deceleration fall interval) in which the deceleration is increased nonlinearly (in an S-shaped manner) so as to change the absolute value of Jerk in a curve (for example, parabolically) and is sometimes written as “Jerk 3” hereinafter. The sixth interval is an interval (a constant deceleration interval) in which the deceleration is constant. The seventh interval is an interval (the second decrease interval, deceleration decrease interval, or deceleration fall interval) in which the deceleration is reduced nonlinearly (in an S-shaped manner) so as to change the absolute value of Jerk in a curve (for example, parabolically) and is sometimes written as “Jerk 4” hereinafter. The fifth to seventh intervals constitute a deceleration period in which the object is decelerated so as to change the deceleration nonlinearly.

In this case, “acceleration” used in this specification can be defined as an acceleration in the plus direction, and “deceleration” can be defined as an acceleration in the minus direction. That is, “to increase the acceleration” can be defined as “to increase the absolute value of the acceleration in the plus direction, and “to reduce the acceleration” can be defined as “to reduce the absolute value of the acceleration increased in the plus direction. Likewise, “to increase the deceleration” can be defined as “to increase the absolute value of the acceleration in the minus direction”, and “to reduce the deceleration” can be defined as “to reduce the absolute value of the acceleration increased in the minus direction”.

As described above, if the constant speed interval (the fourth interval) of the S-shaped acceleration profile created as shown in FIGS. 3A to 3E is equal to or less than a threshold, a steep force change occurs between an acceleration period and a deceleration period. This can cause vibration in the object and also increase the settling time. Accordingly, in this embodiment, an S-shaped acceleration profile like that shown in FIGS. 3A to 3E is created as a provisional profile. In a case where the length of the constant speed period (the fourth interval) of the provisional profile is equal to or less than the threshold, a driving profile used to drive the object is generated by processing the provisional profile so as not to include a portion in which the absolute value of the Jerk becomes zero between the acceleration period and the deceleration period. Driving the object in accordance with the driving profile generated in this manner makes it possible to reduce a steep force change between the acceleration period and the deceleration period.

A case in which the S-shaped acceleration profile shown in FIGS. 3A to 3E is created as a provisional profile will be described first, and Examples 1 to 3 in each of which the created provisional profile is processed to generate a driving profile will be described next. The following processes (calculations and processing) can be executed by an information processing apparatus (profiler). The information processing apparatus can be configured by a computer including a processor such as a CPU (Central Processing Unit) and a storage unit such as a memory.

The S-shaped acceleration profile shown in FIGS. 3A to 3E can be created by using command values (designated values). The command values can be values (information) set in advance for the designation of parameter values (commands) concerning the creation of an S-shaped acceleration profile. In this embodiment, the following can be designated as command values: target driving amount: X, maximum speed: V, maximum acceleration: A, time of Jerk 1: T1, time of Jerk 2: T2, time of Jerk 3: T3, time of Jerk 4: T4, and time threshold of constant speed interval: T_{threshold}. The target driving amount X is the driving amount (moving amount) by which the object should be driven by the generated driving profile. The threshold T_{threshold} is a threshold for determining whether to process (switch) the profile in a period including Jerk 2 and Jerk 3 and can be set to zero or a small numerical value close to zero. The threshold T_{threshold} can be set to the length of a constant speed interval when the vibration caused in the object driven by an S-shaped acceleration profile as a provisional profile reaches a specified value.

In this case, Jerk 1 means an interval in which the absolute value of acceleration increases in the positive direction relative to the driving direction of the object (that is, an interval in which the acceleration increases). Jerk 2 means an interval in which the absolute value of acceleration decreases in the positive direction relative to the driving direction of the object (that is, an interval in which the acceleration decreases). Jerk 3 means an interval in which the absolute value of acceleration increases in the negative direction relative to the driving direction of the object (that is, an interval in which the deceleration increases). Jerk 4 means an interval in which the absolute value of acceleration decreases in the negative direction relative to the driving direction of the object (that is, an interval in which the deceleration decreases).

A constant acceleration time Tₐ, a constant deceleration time T_{b}, and a constant speed time Tₘ are obtained by the following equations. The constant acceleration time Tₐ is equivalent to the length of a constant acceleration interval (the second interval). The constant deceleration time T_{b} is equivalent to the length of a constant deceleration interval (the sixth interval). The constant speed time Tₘ is equivalent to the length of a constant speed interval (the fourth interval).

Tₐ=V/A−½×(T₁+T₂) (1)

T_{b}=V/A−½×(T₃+T₄) (2)

ω₁=π/T₁ ω₂=π/T₂ ω₃=π/T₃ ω₄=π/T₄ (3)

if (T₁+T₂>T₃+T₄), then

Tₘₐₓ=T₁+T_{2 max}A=0

else then

Tₘₐₓ=T₃+T_{4 max}A=1

if ((Tₐ<=T_{threshold}) or (T_{b}<=T_{threshold})) condition 1

if (ₘₐₓA==0) (constant acceleration time is longer)

Tₐ=T_{threshold}

A=V/(Tₐ+½×Tₘₐₓ) (4)

T_{b}=V/A−½×(T₃+T₄) (5)

else if constant deceleration time is longer

T_{b}=T_{threshold}

A=V/(T_{b}+½×Tₘₐₓ) (4′)

Tₐ=V/A−½×(T₁+T₂) (5′)

This makes it possible to obtain the constant acceleration time Tₐ and the maximum acceleration A.

In this case, the constant speed time Tₘ as a driving condition is calculated.

Letting xₐ be the moving distance during acceleration and x_{b} be the moving distance during deceleration,

$${x}_{a} = ( \frac{A}{2} ) \times ( \frac{{T}_{1}^{2}}{2} - \frac{2}{{ω}_{1}^{2}} ) + ( \frac{A}{2} ) \times {T}_{1} \times ( \frac{V}{A} - \frac{( {T}_{C} + {T}_{A} )}{2} ) + ( \frac{A}{2} ) \times {( \frac{V}{A} - \frac{( {T}_{1} + {T}_{2} )}{2} )}^{2} + ( V - ( \frac{A}{2} ) \times {T}_{2} ) \times {T}_{2} + ( \frac{A}{2} ) \times ( \frac{{T}_{2}^{2}}{2} + \frac{2}{{ω}_{2}^{2}} ) \qquad ( 6 )$$

$${x}_{b} = ( \frac{A}{2} ) \times ( \frac{{T}_{4}^{2}}{2} - \frac{2}{{ω}_{1}^{2}} ) + ( \frac{A}{2} ) \times {T}_{4} \times ( \frac{V}{A} - \frac{( {T}_{4} + {T}_{3} )}{2} ) + ( \frac{A}{2} ) \times {( \frac{V}{A} - \frac{( {T}_{4} + {T}_{3} )}{2} )}^{2} + ( V - ( \frac{A}{2} ) \times {T}_{3} ) \times {T}_{3} + ( \frac{A}{2} ) \times ( \frac{{T}_{3}^{2}}{2} + \frac{2}{{ω}_{3}^{2}} ) \qquad ( 7 )$$

$${T}_{m} = ( X - {x}_{a} - {x}_{b} ) / V \qquad ( 8 )$$

This makes it possible to obtain the constant speed time Tₘ.

if (Tₘ<=T_{threshold}) (constant speed time is equal to or less than threshold) condition 2

Tₘ=T_{threshold}

A=2×V/Tₘₐₓ (9)

Rearranging equations (6), (7), and (8) upon substituting equation (9) into them can obtain equation (10).

V=X/(Tₘ−(kₐ+k_{b}+k_{c})) (10)

Note, however,

$${k}_{a} = - {T}_{3} \times ( 1 - \frac{{T}_{3}}{{T}_{max}} ) - {T}_{2} \times ( 1 - \frac{{T}_{2}}{{T}_{max}} ) - ( \frac{{T}_{4}^{2}}{2} - \frac{2}{{ω}_{4}^{2}} ) / {T}_{max} - {( \frac{{T}_{max}}{2} - \frac{( {T}_{4} + {T}_{3} )}{2} )}^{2} / {T}_{max}$$

$${k}_{b} = - {T}_{4} \times ( \frac{{T}_{max}}{2} - \frac{( {T}_{4} + {T}_{3} )}{2} ) / {T}_{max} - ( \frac{{T}_{3}^{2}}{2} + \frac{2}{{ω}_{3}^{2}} ) / {T}_{max} - ( \frac{{T}_{2}^{2}}{2} + \frac{2}{{ω}_{2}^{2}} ) / {T}_{max} - {( \frac{{T}_{max}}{2} - \frac{( {T}_{2} + {T}_{1} )}{2} )}^{2} / {T}_{max}$$

$${k}_{c} = - {T}_{2} \times ( \frac{{T}_{max}}{2} - \frac{( {T}_{2} + {T}_{1} )}{2} ) / {T}_{max} - ( \frac{{T}_{1}^{2}}{2} + \frac{2}{{ω}_{1}^{2}} ) / {T}_{max}$$

A maximum acceleration Aa is obtained by recalculation using V obtained by equation (10).

Aₐ=2×V/Tₘₐₓ

if (|Aₐ|>|A|) ※ If the recalculated maximum acceleration |Aₐ| is larger than the designated maximum acceleration |A|, equation (8) is rearranged about V using the maximum acceleration A.

a=1/A

b=Tₘ+(T₂+T₃)/2

c=A/2×(¼−2/π²)×(T₁²−T₂²−T₃²+T₄²)−x

From the formula for the solution,

$$V = \frac{- b \pm \sqrt{{b}^{2} - 4 ac}}{2 a}$$

V is obtained. In this case, “−” (negative) of “±” of the formula for the solution is inconceivable, and hence calculation is made with “+” (positive). Subsequently, all calculations are made by the formulae for the solutions with the positive signs.

Else if ※ the recalculated maximum acceleration |Aₐ| is equal to or less than the designated maximum acceleration |A|, then

A=Aₐ the maximum acceleration is updated.

Tₐ and T_{b} are recalculated by substituting the updated value of A into equations (1 ) and (2).

From now on, a final profile is calculated. Speeds and positions in the respective intervals are calculated based on

Jerk 1 (first interval in FIGS. 3A to 3E) end time: t₁=T₁

constant acceleration (second interval in FIGS. 3A to 3E) end time: t₂=t₁+Tₐ

Jerk 2 (third interval in FIGS. 3A to 3E) end time t₃: t₃=t₂+T₂

constant speed (fourth interval in FIGS. 3A to 3E) end time: t₄=t₃+Tₘ

Jerk 3 (fifth interval in FIGS. 3A to 3E) end time t₅: t₅=t₄+T₃

constant deceleration (sixth interval in FIGS. 3A to 3E) end time: t₆=t₅+T_{b}

Jerk 4 (seventh interval in FIGS. 3A to 3E) end time t₇: t₇=t₆+T₄

Letting v₁ be the speed at t₁ and x₁ be the position at t₁, then

v₁=(A/2)×T₁ x₁=(A/2)×(½×T₁²=2/ω₁²)

Letting v₂ be the speed at t₂ and x₂ be the position at t₂, then

v₂=v₁+A×Tₐ x₂=x₁+v₁×Tₐ+½×A×Tₐ²

Letting v₃ be the speed at t₃ and x₃ be the position at t₃, then

v₃=V x₃=x₂+v₂×T₂+(A/2)×(½×T₂²=2/ω₂²) (11)

Letting v₄ be the speed at t₄ and x₄ be the position at t₄, then

v₄=V x₄=x₃+v₃×Tₘ (12)

Letting v₅ be the speed at t₅ and x₅ be the position at t₅, then

v₅=v₄−(A/2)×T₃ x₅=x₄+v₄×T₃−(A/2)×(½×T₃²=2/ω₃²) (13)

Letting v₆ be the speed at t₆ and x₆ be the position at t₆, then

v₅=(A/2)×T₄ x₅=X−(A/2)×(½×T₄²=2/ω₄²)

Speed at t₇: v₇=0 and position at t₇: x₇=X.

A position profX, a speed profV, an acceleration profA, a Jerk profJk, and Snap profSp of a profile at each time t are calculated by the following equations.

if (time<t₁): Jerk 1 interval (first interval in FIGS. 3A to 3E), then

t=time

profX=(A/2)×(t²/2+1/ω₁²×cos(ω₁×t)−1/ω₁²)

profV=(A/2)×(t−1ω₁²×sin(ω₁×t))

profA=(A/2)×(1−cos(ω₁×t)) acceleration calculation equation

profJk=(A/2)×ω₃×sin(ω₁×t) Jerk calculation equation

profSp=(A/2)×ω₃²×cos(ω₁×t) Snap calculation equation

else if (time<=t₂): constant acceleration interval (second interval in FIGS. 3A to 3E)

t=time−t₁

profX=x₁+v₁×t+½×A×t²

profV=v₁+A×t

profA=A

profJk=0

profSp=0

else if (time<=t₃): Jerk 2 interval (third interval in FIGS. 3A to 3E)

t=time−t₂

profX=x₂+v₂×t+(A/2)×(t²/2−1/ω₂²×cos(ω₂×t)+1/ω₂²)

profV=v₁+(A/2)×(t+1/ω₂×sin(ω₂×t))

profA=(A/2)×(1+cos(ω₂×t))

profJk=−(A/2)×ω₂×sin(ω₂×t)

profSp=−(A/2)×ω₂²×cos(ω₂×t)

else if (time<t₄): constant speed interval (fourth interval in FIGS. 3A to 3E)

t=time−t₃

profX=x₃+v₃×t

profV=V

profA=0

profJk=0

profSp=0

else if (time<=t₅): Jerk 3 interval (fifth interval in FIGS. 3A to 3E)

t=time−t₄

profX=x₄+v₄×t−(A/2)×(t²/2−1/ω₃²×cos(ω₃×t)+1/ω₃²)

profV=v₄−(A/2)×(t−1/ω₃×sin(ω₃×t))

profA=−(A/2)×(1−cos(ω₃×t))

profJk=−(A/2)×ω₃×sin(ω₃×t)

profSp=−(A/2)×ω₃²×cos(ω₃×t)

else if (time<=t₆): constant deceleration interval (sixth interval in FIGS. 3A to 3E)

t=time−t₅

profX=x₅+v₅×t÷½×A×t²

profV=v₅−A×t

profA=−A

profJk=0

profSp=0

else: Jerk 4 interval (seventh interval in FIGS. 3A to 3E)

t=time−t₆

profX=x₆+v₆×t−(A/2)×(t²/2−1/ω₄²×cos(ω₄×t)+1/ω₄²)

profV=v₆−(A/2)×(t−1/ω₄×sin(ω₄×t))

profA=−(A/2)×(1+cos(ω₄×t))

profJk=(A/2)×ω₄×sin(ω₄×t)

profSp=(A/2)×ω₄²×cos(ω₄×t)

The S-shaped acceleration profile (provisional profile) shown in FIGS. 3A to 3E is the one obtained by plotting these values. The above is the detailed creating process (derivation process) for the S-shaped acceleration profile (provisional profile) shown in FIGS. 3A to 3E. The following will describe Examples 1 to 3 of generating a driving profile by processing the provisional profile created in the above manner.

### EXAMPLE 1

Example 1 of generating a driving profile by processing a provisional profile will be described below. If the S-shaped acceleration profile (provisional profile) shown in FIGS. 3A to 3E satisfies condition 2 described above (note that if condition 1 holds, condition 2 also holds), the S-shaped acceleration profile switches from the profile indicated by the solid line to the profile indicated by the broken line in FIGS. 1A to 1E. In this case, the constant speed interval between acceleration and deceleration (the transition point between Jerk 2 and Jerk 3) becomes zero if T_{threshold}=0, and steeply changes like becoming zero even if T_{threshold} is short.

In this case, in Example 1, the period including the Jerk 2 interval (third interval) and the Jerk 3 interval (fifth interval) is recalculated, and the provisional profile is processed (switched) so as to form one S-shaped acceleration profile throughout the period. That is, the provisional profile is processed to change the absolute value of Jerk in a curve (for example, parabolically) throughout the period.

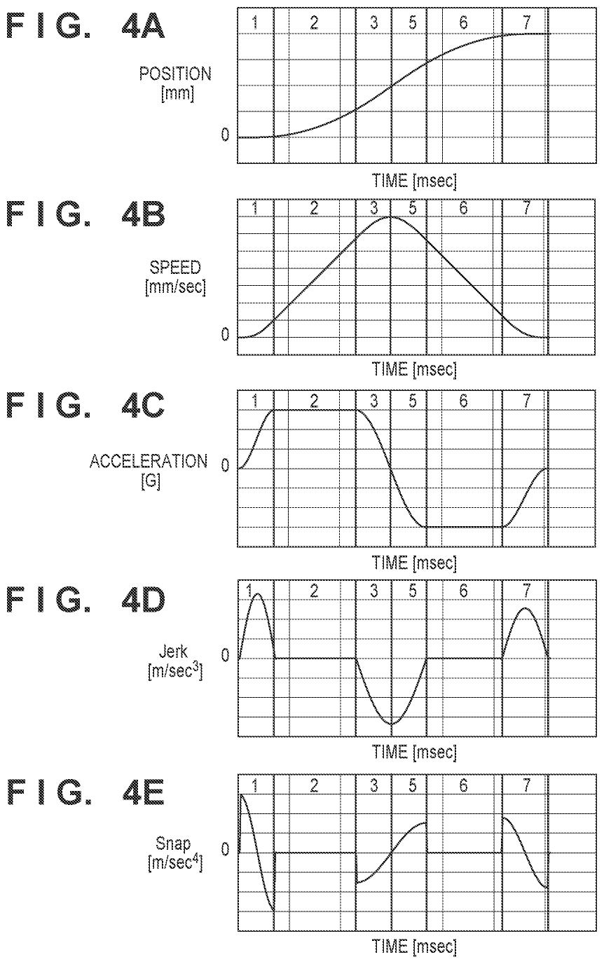

More specifically, if condition 2 holds, the end position of Jerk 3 is x₅ according to equations (11), (12), and (13). If the overall period including the third to fifth intervals as shown in FIGS. 4A to 4E is one S-shaped acceleration profile, a position x₅ₘ and a speed v₅ₘ at the end time of Jerk 3 can be obtained by

T_{threshold}=0

t=T₂+T₃ ω_{2 3}^{m}π/t (14)

v₅ₘ=v₂+A×(t+1/ω_{2 3}×sin(ω_{2 3}×t))−A×t (15)

x₅ₘ=x₂v₂×t+A×(t²/2−1/ω_{2 3}²×cos(ω_{2 3}×t))+1/ω_{2 3}²)−A/2×t² (16)

Note, however, that the position x₅ and the position x₅ₘ differ from each other even if the elapsed time oft remains the same upon changing of the profile. Accordingly, the time tin equation (16) is obtained such that x₅ obtained from equations (11), (12), and (13) satisfies x₅=x₅ₘ and is recalculated according to the following procedure such that the end position upon changing of the profile becomes the same position based on the original profile.

x₂+v₂×t+A×(t²/2−1/ω_{2 3}²×cos(ω_{2 3}×t)+1/ω_{2 3}²)−A/2't²=x₅

is rearranged about t into

2×A/π²×t²+v2×t+(x2−x5)=0

### If

a=2×A/π²

b=v2

c=(x2−x5)

then t is obtained by the following formula for the solution

$$t = \frac{- b + \sqrt{{b}^{2} - 4 ac}}{2 a}$$

Recalculating equations (14), (15), and (16) with t can reduce the discontinuity caused in the profile before and after processing (before and after switching). That is, re-processing the provisional profile after the processing can reduce the discontinuity caused in the provisional profile before the processing.

In addition, the following times are recalculated:

Jerk 3 end time: t₅=t₂+t

constant deceleration end time: t₆=t₅+T_{b}

Jerk 4 end time: t₇=t₆+T₄

The final profile under this condition can be obtained by

else if (time<=t₃): Jerk 2 interval (third interval in FIGS. 4A to 4E) and

else if (time<=t₅): Jerk 3 interval (fifth interval in FIGS. 4A to 4E)

t=time−t₂

profX=x₂+v₂×t+A×(t²/2−1/ω_{2 3}²×cos(ω_{2 3}×t))+1/ω_{2 3}²)−A/2×t²

profV=v₂+A×(t−1/ω_{2 3}×sin(ω_{2 3}×t))−A×t

profA=A×(1+cos(ω_{2 3}×t))−A

profJk=−A×ω_{2 3}×sin(ω_{2 3}×t)

profSp=−A×ω_{2 3}²×cos(ω_{2 3}×t)

FIGS. 4A to 4E show a provisional profile after the processing.

In this manner, the provisional profile is processed, and the provisional profile after the processing is determined (switched) as a driving profile used to drive an object. That is, according to Example 1, the provisional profile is processed so as to make the absolute value of the Jerk include no zero between the third interval and the fifth interval, and the provisional profile after the processing is determined as a driving profile. This reduces the steep change in Jerk and Snap between (at the transition point) Jerk 2 (third interval) and Jerk 3 (fifth interval) respectively denoted by reference numerals 10 and 11 on the broken lines in FIGS. 1D and 1E. That is, as shown in FIGS. 4D and 4E, it is possible to smoothly change the Jerk and the Snap between the third interval and the fifth interval and to reduce (suppress) the excitation in the drive axis, the non-drive axes, and the main body structure at this timing.

### EXAMPLE 2

Example 2 of generating a driving profile by processing a provisional profile will be described below. In Example 2, if the S-shaped acceleration profile shown in FIGS. 3A to 3E satisfies condition 2 described above, the provisional profile is processed so as to linearly change the absolute value of the acceleration in a period including Jerk 2 (third interval) and Jerk 3 (fifth interval). That is, in Example 2, the provisional profile is processed to switch to a trapezoidal acceleration profile in the period including the third interval and the fifth interval.

More specifically, if condition 2 holds, the end position of Jerk 2 is obtained according to equation (11). If, however, the profile is changed to a trapezoidal acceleration profile, a speed v₃ₘ and a position x₃ₘ at the end time of Jerk 2 are obtained by

v₃ₘ=½×A×t+v₂ (17)

x₃ₘ=⅓×A×t²+v₂×t+x₂ (18)

The following formula is used to calculate t when x₃ obtained by equation (11) and x₃ₘ obtained by equation (18) are equal to each other.

⅓×A×t²+v₂×t+x₂−x₃=0

a=⅓×A

b=v₂

c=(x₂₋x₃)

In this case, t is obtained by the following formula for the solution,

$$t = \frac{- b + \sqrt{{b}^{2} - 4 ac}}{2 a}$$

and v₃ₘ and x₃ₘ are respectively recalculated according to equations (17) and (18). At this time, t is set as t₃ₘ.

Subsequently, the speed and the position at the Jerk 3 end time of the provisional profile before processing (switching) respectively become v₅ and x₅ obtained by equations (11), (12), and (13). A speed v₅ₘ and a position x₅ₘ at the Jerk 3 end time of the provisional profile processed (changed) into a trapezoidal acceleration profile can be obtained by

v₅ₘ=−½×A×t+v₅ₘ (19)

x₅ₘ=−⅙×A×t²+v₅ₘ×t+x₅ₘ (20)

If x₅ₘ obtained by equation (20) is equal to x₅, t is calculated by

−⅙×A×t²+v₅ₘ×t+x₅ₘ−x₅=0

a=−⅙×A

b=v₅ₘ

c=(x₅ₘ₋x₅)

In this case, using the following formula for the solution

$$t = \frac{- b + \sqrt{{b}^{2} - 4 ac}}{2 a}$$

will obtain t when x₅ₘ is equal to x₅. At this time, t is set as t₅ₘ.

The value obtained above is reflected in the pre-calculation of the profile according to the following equations.

T₂=t₃ₘ

t₃=t₂+T₂

x₃=x₃ₘ

v₃=v₃ₘ

V=v₃

t₄=t₃×Tₘ

v₄=V

x₄=x₃+v₃×Tₘ

T₃=t₅ₘ

t₅=t₄×T₃

x₅=x₅ₘ

v₅=v₅ₘ

t₆=t₅×T_{b}

t₇=t₆×T₄

The final profile under this condition can be obtained by

else if (time<=t₃): Jerk 2 interval

t=time−t₂

profX=x₂+v₂×t+A/2×t²−⅙×(A/T₂)×t³

profV=v₂+A×t−½×(A/T₂)×t²

profA=A−A/T₂×t

profJk=−A/T₂

profSp=0

else if (time<=t₅): Jerk 3 interval

t=time−t₄

profX=x₄+v₄×t−⅙×(A/T₃)×t³

profV=v₄−½×(A/T₃)×t²

profA=A/T₃×t

profJk=−A/T₃

profSp=0

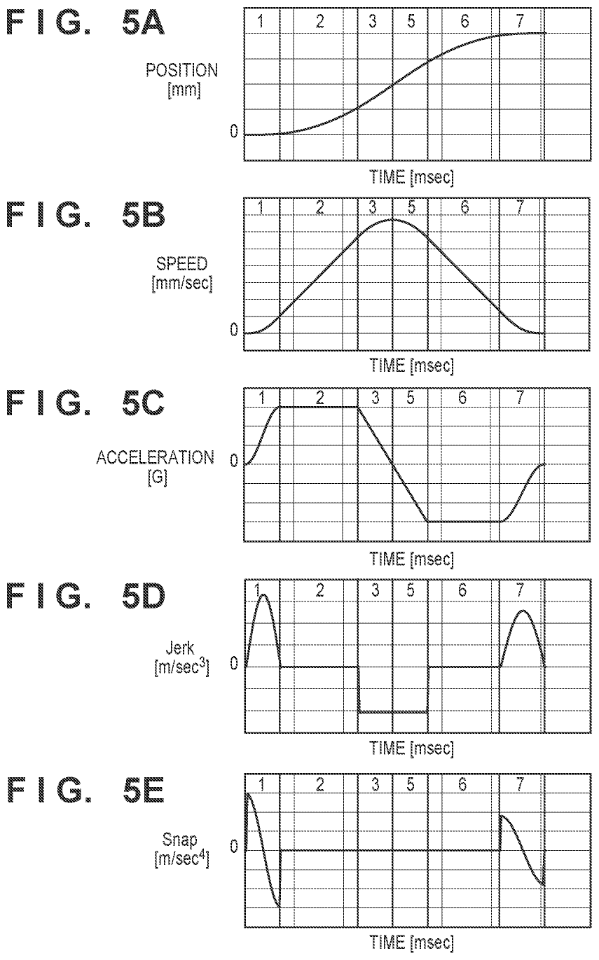

FIGS. 5A to 5E shows the provisional profile after the processing.

In this manner, the provisional profile is processed, and the provisional profile after the processing is determined (switched) as a driving profile used for driving the object. That is, according to Example 2, the provisional profile is processed so as to make the absolute value of Jerk include no zero between the third interval and the fifth interval. The provisional profile after the processing is determined as a driving profile. This reduces steep force changes in Jerk and Snap between (at the transition point) Jerk 2 (third interval) and Jerk 3 (fifth interval) denoted by reference numerals 10 and 11 at the broken lines in FIGS. 1D to 1E. That is, as shown in FIGS. 5D and 5E, in the period including the third interval and the fifth interval, the Jerk linearly changes, and the Snap becomes zero. In this manner, the force change is reduced, and the excitation in the drive axis, the non-drive axes, and the main body structure is suppressed at this timing.

Assume that the object is the stage of an exposure apparatus. In this case, in a damping control mechanism for reducing the vibration of the apparatus main body due to the stage reaction force, since the reaction force exhibits a simple linear change, it is easy to control the reaction force. This makes it possible to improve the controllability of the vibration damping of the apparatus main body and the lens. In addition, at Jerk 4 (the seventh interval in FIGS. 5A to 5E), the profile has returned to the S-shaped acceleration profile that is suitable for the settling of the drive axis, and hence the stage drive axis can be quickly settled as compared with the trapezoidal acceleration profile. This makes it possible to shorten the settling times of the stage and the apparatus main body, thereby providing an exposure apparatus with an improved throughput.

### EXAMPLE 3

Example 3 of generating a driving profile by processing a provisional profile will be described below. In Example 3, if the S-shaped acceleration profile shown in FIGS. 3A to 3E satisfies condition 2 described above, the provisional profile is processed so as to linearly change the absolute value of the acceleration in part of a period including Jerk 2 (third interval) and Jerk 3 (fifth interval). That is, the provisional profile is processed so as to linearly change the absolute value of the acceleration in a period including a part of the later phase (later phase portion) of Jerk 2 (third interval) and a part of the early phase (early phase portion) of Jerk 3 (fifth interval). In other words, a profile is configured so as to set an S-shaped acceleration profile midway along Jerk 2 (third interval), switched to a trapezoidal acceleration profile configured to linearly change the absolute value of acceleration midway along Jerk 3 (fifth interval), and returned to an S-shaped acceleration profile midway along Jerk 3.

More specifically, if condition 2 holds, an elapsed time t₃₂ of a middle part of Jerk 2 and a position x₃₂ and a speed v₃₂ at this point of time are obtained by

t t₃₂=T₂/2

t₃₂=t₂+t t₃₂

v₃₂=v₂+(A/2)×(t t₃₂+1/ω₂×sin(ω₂×t t₃₂))

x₃₂=x₂+v₂×t t₃₂+(A/2)×(t t₃₂²/2−1/ω₂²×cos(ω₂×t t₃₂)+1/ω₂²)

An elapsed time t₅₂ of a middle part of Jerk 3 and a position x₅₂ and a speed v₅₂ at this point of time can be obtained by

t t₅₂=T₃/2

t₅₂=t₄+t t₅₂

v₅₂=v₄+(A/2)×(t t₅₂−1/ω₃×sin(ω₃×t t₅₂))

x₅₂=x₄+v₄×t t₅₂−(A/2)×(t t₅₂²/2−1/ω₃²×cos(ω₃×t t₅₂)−1/ω₃²)

The final profile under this condition can be obtained by

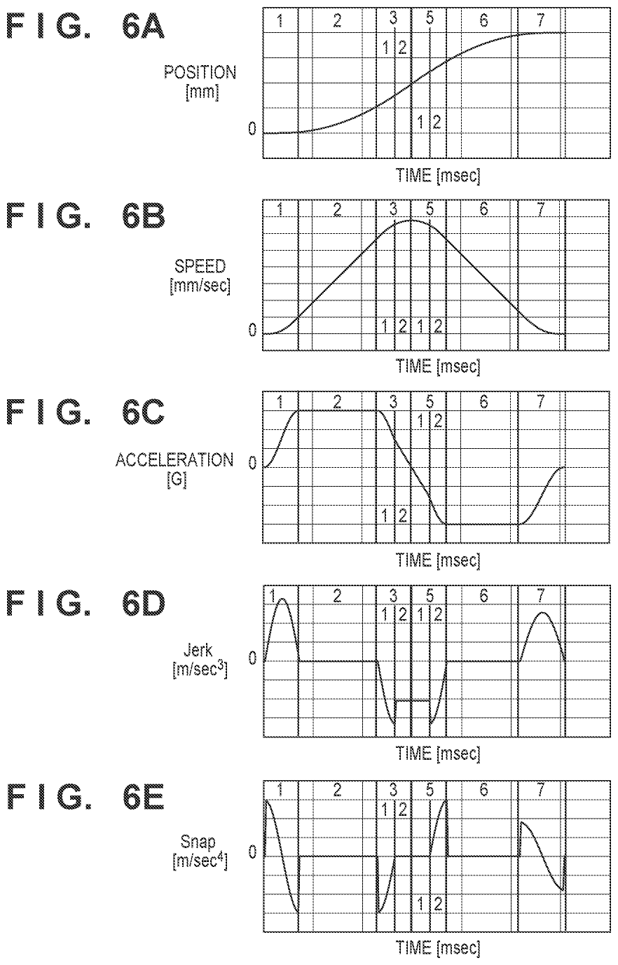

else if (time<=t₃) Jerk 2 third interval in FIGS. 6A to 6E

if (time<=t₃₂): 3-1st interval in FIGS. 6A to 6E

t=time−t₂

profX=x₂+v₂×t+(A/2)×(t²/2−1/ω₃²×cos(ω₂×t)+1/ω₂²)

profV=v₂−(A/2)×(t−1/ω₂×sin(ω₂×t))

profA=−(A/2)×(1−cos(ω₂×t))

profJk=−(A/2)×ω₂×sin(ω₂×t)

profSp=−(A/2)×ω₂²×cos(ω₂×t)

else: 3-2nd interval in FIGS. 6A to 6E.

t=time−t₃₂

profX=x₃₂+v₃₂×t+A/4×t²− 1/12×(A/t t₃₂))×t³

profV=v₃₂+A/2×t−¼×(A/t t₃₂))×t²

profA=A/2−½×(A/t t₃₂))×t

profJk=−½×(A/t t₃₂)

profSp=0

else if (time<=t₅): Jerk 3 fifth interval in FIGS. 6A to 6E

else if (time<=t₅₂): 5-1st interval in FIGS. 6A to 6E

t=t₅₂−time

profX=x₅₂−(v₅₂×t+A/4×t²− 1/12×(A/t t₃₅))×t³)

profV=v₅₂+A/2×t−¼×(A/t t₅₂))×t²

profA=−A/2+½×(A/t t₅₂))×t

profJk=−½×(A/t t₅₂)

profSp=0

else: 5-2nd interval in FIGS. 6A to 6E

t=time−t₄

profX=x₄+v₄×t+(A/2)×(t²/2−1/ω₃²×cos(ω₃×t)−1/ω₃²)

profV=v₄−(A/2)×(t−1/ω₃×sin(ω₃×t))

profA=−(A/2)×(1−cos(ω₃×t))

profJk=−(A/2)×ω₃×sin(ω₃×t)

profSp=−(A/2)×ω₃²×cos(ω₃×t)

In this manner, the provisional profile is processed, and the provisional profile after the processing is determined (switched) as a driving profile used to drive the object. That is, according to Example 2, the provisional profile is processed so as to make the absolute value of Jerk include no zero between the third interval and the fifth interval. The provisional profile after the processing is determined as a driving profile. This reduces steep force changes between (at the transition point) Jerk 2 (third interval) and Jerk 3 (fifth interval) denoted by reference numerals 10 and 11 at the broken lines in FIGS. 1D to 1E. That is, as shown in FIGS. 6D and 6E, in the period including the 3-2nd interval (the later phase portion of the third interval) and the 5-1st interval (the early phase portion of the fifth interval), the Jerk linearly changes, and the Snap becomes zero. In this manner, the force change is reduced, and the excitation in the drive axis, the non-drive axes, and the main body structure is suppressed at this timing.

Setting an S-shaped acceleration profile in the 3-1st interval (the later phase portion of the third interval) and the 5-2nd interval (the early phase portion of the fifth interval) can suppress the maximum voltage to be applied to the coil when, for example, the stage is driven by using a linear motor. More specifically, the absolute value of the acceleration becomes maximum at the end time of the first interval and the end time of the fifth interval, and the current value flowing through the coil at this time becomes maximum. A voltage is determined by the resistance and current value of the coil and changes in the inductance and current of the coil, that is, Jerk. In Example 3, since the Jerk at the maximum acceleration approaches zero and becomes small, this profile can suppress the maximum voltage to be applied to the coil as compared with the trapezoidal acceleration profile.

### EXAMPLE 4

This embodiment has exemplified the case in which the S-shaped acceleration profile generated as a provisional profile is a COS (sine wave) acceleration profile. However, the S-shaped acceleration profile may be a (1-COS)² acceleration profile or log (logarithmic) acceleration profile.

In addition, in this embodiment, at least part of the period including Jerk 2 (third interval) and Jerk 3 (fifth interval) as an interval in which the profile is switched (that is, an interval in which the profile is processed). However, the present invention is not limited to this. For example, similar effects can be obtained in a case in which after the object is decelerated in a deceleration period (between the fifth interval and the seventh interval), the driving direction is changed, and the object is accelerated again. In this case as well, similar effects can be obtained by processing (switching) the profile between Jerk 4 (seventh interval) and Jerk 1 (first interval), as described in Examples 1 to 3.

For example, a provisional profile can be created by adjusting the length of a stop period in which the object is stopped between a deceleration period (between the fifth interval and the seventh interval) and a second acceleration period in which the object is re-accelerated after the deceleration period so as to include the deceleration period and the second acceleration period. The second acceleration period can be configured in the same manner as the acceleration period (between the first interval and the third interval). In this case, in a case where the stop period is equal to or less than the second threshold, the provisional profile is processed so as to make the absolute value of the Jerk include no zero between the deceleration period and the second acceleration period, and the provisional profile after the processing can be determined as a driving profile. The second threshold can be set to the length of the stop period when the vibration caused in the object reaches a specified value by using an experiment, simulation, or the like. The second threshold can be set to, for example, zero or a value near zero.

The provisional profile can be processed in a similar manner to Examples 1 to 3. Applying Example 1 makes it possible to process the provisional profile so as to change the absolute value of the Jerk in a curve (for example, parabolically) throughout period including the seventh interval of the deceleration period and the first interval of the second acceleration period. Applying Examples 2 and 3 makes it possible to process the provisional profile so as to change the absolute value of the acceleration linearly in the period including the later phase portion of the deceleration period and the early phase portion of the second acceleration period. The later phase portion of the deceleration period is at least part of the seventh interval of the deceleration period. The early phase portion of the second acceleration period is at least part of the first interval of the second acceleration period.

### Second Embodiment

The second embodiment of the present invention will be described. This embodiment will exemplify a procedure in a generating method for the driving profile described in the first embodiment. Note that the second embodiment basically inherits the first embodiment, and each step in the procedure described below can be applied to the calculation method (the preparing method and the generating method) described in the first embodiment.

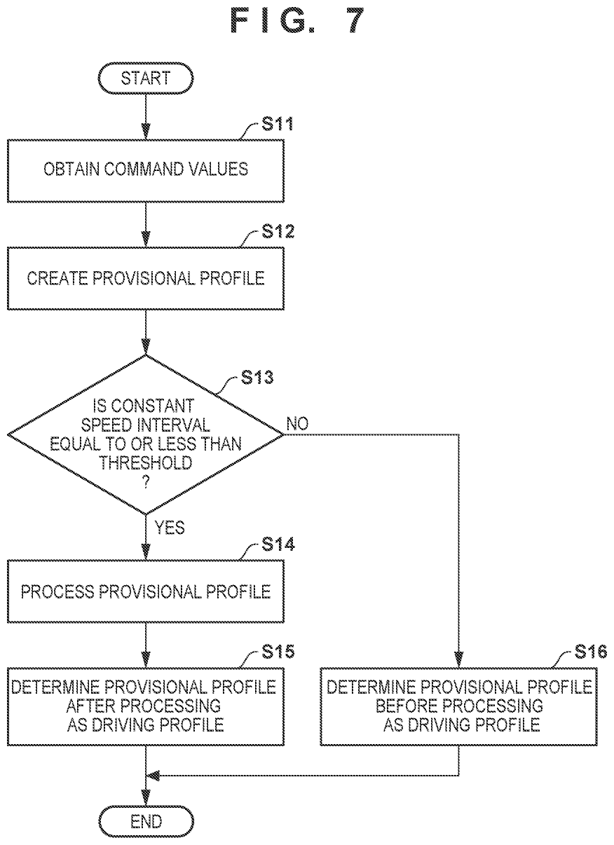

FIG. 7 is a flowchart showing a generating method of generating a driving profile for driving an object. Each step in the flowchart shown in FIG. 7 can be executed by the information processing apparatus.

In step S11, the information processing apparatus obtains command values (designated values and parameter values) used to create a provisional profile (S-shaped acceleration profile). As described above, the command values include a target driving amount by which the object should be driven by the driving profile. In addition to the target driving amount, the command values include the maximum speed, the maximum acceleration, the Jerk 1 (first interval) time, the Jerk 2 (third interval) time, the Jerk 3 (fifth interval) time, the Jerk 4 (seventh interval) time, and a constant speed interval (fourth interval) time threshold.

In step S12, the information processing apparatus creates a provisional profile based on the command values obtained in step S11. A provisional profile is created by adjusting the length of the constant speed interval (the fourth interval) between an acceleration period (between the first interval and the third interval) and a deceleration period (between the fifth interval and the seventh interval) so as to include the acceleration period and the deceleration period and achieve the target driving amount. A provisional profile can be created as an S-shaped acceleration profile. A creating method for a provisional profile is the same as in the first embodiment, and hence a detailed description of the method will be omitted.

In step S13, the information processing apparatus determines whether the length of the constant speed interval in the provisional profile created in step S12 is equal to or less than a threshold. If the information processing apparatus determines that the length of the constant speed interval is equal to or less than the threshold, the process advances to step S14. In step S14, the information processing apparatus processes the provisional profile so as to make the absolute value of the Jerk include no zero between an acceleration period and a deceleration period (for example, so as to make the absolute value of the Jerk fall within a predetermined range including no zero). A processing method for a provisional profile is the same as in the first embodiment, and hence a detailed description of the method will be omitted. Any of Examples 1 to 3 can be applied as the processing method for the provisional profile in step S14. In step S15, the information processing apparatus determines the provisional profile processed in step S14 as a driving profile used to drive the object.

If the information processing apparatus determines in step S13 that the length of the constant speed interval is larger than the threshold, the process advances to step S16. In step S16, the information processing apparatus determines the provisional profile (the provisional profile before the processing) created in step S12 as a driving profile used to drive the object.

### Embodiment of Lithography Apparatus

An embodiment of a lithography apparatus will be described below. This embodiment will exemplify an exposure apparatus that transfers a pattern of an original plate (mask) onto a substrate as a lithography apparatus to which the generating method for the driving profile described in the first and second embodiments is applied. Note, however, that the lithography apparatus is not limited to an exposure apparatus and may be, for example, an imprint apparatus that forms a pattern of an imprint material on a substrate by using an original plate (mold) or a planarization apparatus that planarizes a composition on a substrate by using an original plate (mold). The generating methods for the driving profiles described in the first and second embodiments can be used to generate a driving profile for a substrate or original plate.

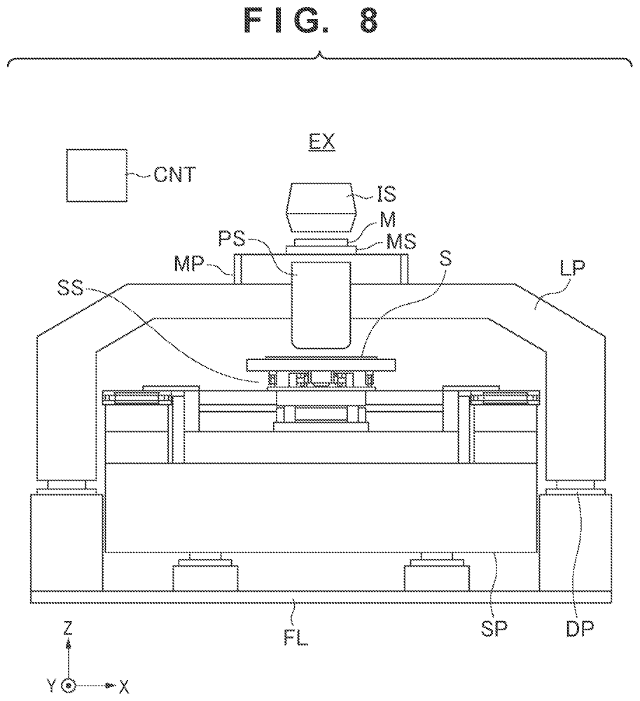

FIG. 8 is a schematic view showing an example of the arrangement of an exposure apparatus EX. The exposure apparatus EX is, for example, a lithography apparatus that is used for a lithography process as a manufacturing process for a device such as a semiconductor device or liquid crystal display device and configured to form a pattern on a substrate by using an original plate. The exposure apparatus EX performs an exposure process of transferring a pattern of a mask M onto a substrate S by exposing the substrate S through a mask (reticle) M as an original plate. In this embodiment, the exposure apparatus EX uses the step and repeat scheme. Note, however, that the step and scan scheme or another exposure scheme can be used for the exposure apparatus EX. Referring to FIG. 8, directions are indicated with reference to an XYZ coordinate system with a plane parallel to a surface of the substrate S being defined as an X-Y plane.

As shown in FIG. 8, the exposure apparatus EX includes a stage surface plate SP, a substrate stage SS, a lens barrel surface plate LP, a damper DP, a projection optical system PS, an illumination optical system IS, a mask surface plate MP, a mask stage MS, and a control unit CNT. The control unit CNT is configured by a computer (information processing apparatus) including a processor such as a CPU (Central Processing Unit) and a storage unit such as a memory and controls an exposure process for the substrate S by controlling each unit of the exposure apparatus EX.

The stage surface plate SP is supported on a floor FL through a mount (not shown). The substrate stage SS is provided on the stage surface plate SP. The substrate stage SS can be configured as a positioning apparatus that positions the substrate S by moving the substrate S on the stage surface plate SP while holding the substrate S. The lens barrel surface plate LP is supported on the floor FL through the damper DP. The projection optical system PS and the mask surface plate MP are provided on the lens barrel surface plate LP. The mask stage MS is movably (slidably) provided on the mask surface plate MP. The illumination optical system IS is provided above the mask stage MS. When exposure is performed, the mask M is illuminated with the light emitted from a light source (not shown) by using the illumination optical system IS. An image of the pattern of the mask M is projected (formed) on the substrate S by the projection optical system PS.

The control unit CNT of the exposure apparatus EX can execute a pattern forming method of forming a pattern on a substrate. The pattern forming method can include a generating process of generating a driving profile for the substrate S (substrate stage SS), a driving process of driving the substrate S in accordance with the driving profile generated in the generating process, and a forming process of forming a pattern on the substrate driven in the driving process. In the generating process, a driving profile can be generated by using the generating method described in the first and second embodiments. When the step and repeat scheme is used for the exposure apparatus EX, the driving profile can be generated for step-driving the substrate S between exposure processes. When the step and repeat scheme is used for the exposure apparatus EX, the driving profile may be generated to drive the substrate S in a scanning exposure process or generated to step-drive the substrate S.

As described above, driving the substrate S (the substrate stage SS) in accordance with the driving profile generated by using the generating method according to the first and second embodiments makes it possible to reduce the vibration of the substrate S (the substrate stage SS) and implement high positioning accuracy. Therefore, the exposure apparatus EX can provide high-quality devices (devices such as semiconductor devices, magnetic storage media, and liquid crystal display devices) with high throughput and high economic efficiency.

The generating method described in the first and second embodiments may be used to generate a driving profile for the mask M (the mask stage MS). In addition, the information processing apparatus that generates a driving profile by using the generating method described in the first and second embodiments is configured as part of the control unit CNT in the embodiments. However, the present invention is not limited to this, and the information processing apparatus may be configured as an external apparatus of the exposure apparatus EX. In this case, the exposure apparatus EX (control unit CNT) and the control unit CNT can obtain the driving profile generated by the information processing apparatus as an external apparatus from the information processing apparatus.

### Embodiment of Article Manufacturing Method

An article manufacturing method according to the embodiment of the present invention is favorable in, for example, manufacturing such articles as devices (e.g., semiconductor elements, magnetic storage mediums, and liquid crystal display elements). This manufacturing method includes a forming process of forming a pattern on a substrate by using the pattern forming method using the lithography apparatus, a processing process of processing the substrate having undergone the forming process, and a manufacturing process of manufacturing an article from the substrate having undergone the processing process. Also, this manufacturing method can include other known processes (oxidization, film formation, vapor deposition, doping, planarization, etching, photoresist stripping, dicing, bonding, packaging, and so forth). Compared to the conventional ones, the article manufacturing method according to the present embodiment is advantageous in at least one of the performance, quality, productivity, and production cost of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022 -170868 filed on Oct. 25, 2022, which is hereby incorporated by reference herein in its entirety.

What is claimed is:

1. A generating method of generating a driving profile for driving an object, the method comprising:
obtaining a target driving amount by which the object is to be driven by the driving profile;
creating, based on the target driving amount, a provisional profile including an acceleration period in which the object is accelerated so as to change an acceleration nonlinearly and a deceleration period in which the object is decelerated so as to change a deceleration nonlinearly; and
determining the driving profile based on the provisional profile,
wherein in the creating, the provisional profile is created by adjusting a length of a constant speed period in which the object is moved at a constant speed between the acceleration period and the deceleration period so as to achieve the target driving amount, and
wherein in the determining, in a case where the length of the constant speed period of the provisional profile is not more than a threshold, the driving profile is determined by processing the provisional profile so as to make an absolute value of a Jerk include no zero portion between the acceleration period and the deceleration period.

2. The method according to claim 1, wherein the acceleration period includes a first decrease interval in which an acceleration is reduced nonlinearly, the deceleration period includes a second increase interval in which a deceleration increases nonlinearly, and
in the determining, the driving profile is determined by processing the provisional profile so as to change an absolute value of a Jerk in a curve in a period including the first decrease interval of the acceleration period and the second increase interval of the deceleration period.

3. The method according to claim 2, wherein in the determining, the driving profile is determined by processing the provisional profile so as to change an absolute value of a Jerk parabolically in a period including the first decrease interval of the acceleration period and the second increase interval of the deceleration period.

4. The method according to claim 1, wherein in the determining, the driving profile is determined by processing the provisional profile so as to change an absolute value of an acceleration linearly in a period including a later phase portion of the acceleration period and an early phase portion of the deceleration period.

5. The method according to claim 4, wherein
the later phase portion of the acceleration period is at least part of a first decrease interval in which an acceleration decreases nonlinearly among the acceleration period, and
the early phase portion of the deceleration period is at least part of a second increase interval in which a deceleration increases nonlinearly among the deceleration period.

6. The method according to claim 1, wherein in the determining, the driving profile is determined by re-processing the processed provisional profile so as to reduce discontinuity included in the provisional profile after the processing.

7. The method according to claim 1, wherein the threshold is zero.

8. The method according to claim 1, wherein in the determining, in a case where a length of the constant speed period of the provisional profile is larger than the threshold, the provisional profile created in the creating is determined as the driving profile.

9. The method according to claim 1, wherein
the provisional profile include the deceleration period and a second acceleration period in which the object is accelerated after the deceleration period, and is created by adjusting a length of a stop period in which the object is stopped between the deceleration period and the second acceleration period, and
in the determining, in a case where the stop period of the provisional profile is not more than a second threshold, the driving profile is determined by processing the provisional profile so as to make an absolute value of a Jerk include no zero between the deceleration period and the second acceleration period.

10. The method according to claim 9, wherein
the deceleration period includes a second decrease interval in which a deceleration decreases nonlinearly,
the second acceleration period includes a first increase interval in which an acceleration increases nonlinearly, and
in the determining, the driving profile is determined by processing the provisional profile so as to change an absolute value of a Jerk in a curve in a period including the second decrease interval of the deceleration period and the first increase interval of the second acceleration period.

11. The method according to claim 10, wherein in the determining, the driving profile is determined by processing the provisional profile so as to change an absolute value of an acceleration linearly in a period including a later phase portion of the deceleration period and an early phase portion of the second acceleration period.

12. The method according to claim 11, wherein
the later phase portion of the deceleration period is at least part of a second decrease interval in which a deceleration decreases nonlinearly among the deceleration period, and
the early phase portion of the second acceleration period is at least part of a first increase interval in which an acceleration increases nonlinearly among the second acceleration period.

13. A pattern forming method of forming a pattern on a substrate, the method comprising
generating a driving profile for the substrate by using a generating method defined in claim 1;
driving the substrate in accordance with the driving profile generated in the generating; and
forming a pattern on the substrate driven in the driving.

14. An article manufacturing method comprising:
forming a pattern on a substrate by using the pattern forming method defined in claim 13;
processing the substrate having undergone the forming; and
manufacturing an article from the substrate having undergone the processing.

15. A non-transitory computer-readable storage medium storing a program for causing a computer to execute a generation method according to claim 1.

16. An information processing apparatus that generates a driving profile for driving an object and executes
obtaining a target driving amount by which the object is to be driven by the driving profile,
creating, based on the target driving amount, a provisional profile including an acceleration period in which the object is accelerated so as to change an acceleration nonlinearly and a deceleration period in which the object is decelerated so as to change a deceleration nonlinearly, and
determining the driving profile based on the provisional profile,
wherein in the creating, the provisional profile is created by adjusting a length of a constant speed period in which the object is moved at a constant speed between the acceleration period and the deceleration period so as to achieve the target driving amount, and
wherein in the determining, in a case where the length of the constant speed period of the provisional profile is not more than a threshold, the driving profile is determined by processing the provisional profile so as to make an absolute value of a Jerk include no zero portion between the acceleration period and the deceleration period.
